(19) United States
(12) Patent Application Publication
(10) Pub. No.: US 2013/0293082 A1
(43) Pub. Date: Nov. 7, 2013

(54) THERMAL MANAGEMENT OF OLED DEVICES

(71) Applicants: Stephen R. Forrest, Ann Arbor, MI (US); Kevin Bergemann, Ann Arbor, MI (US)

(72) Inventors: Stephen R. Forrest, Ann Arbor, MI (US); Kevin Bergemann, Ann Arbor, MI (US)

(73) Assignee: THE REGENTS OF THE UNIVERSITY OF MICHIGAN, Ann Arbor, MI (US)

(21) Appl. No.: 13/465,942

(22) Filed: May 7, 2012

(51) Int. Cl. H01J 7/24; H01J 9/00

(52) U.S. Cl. 313/46; 29/592.1

(57) ABSTRACT

An electrically powered light source can be constructed with an electroluminescent element operating essentially at room temperature while providing a useful amount of light. A thermal junction located between an OLED and a cover layer of an OLED device is configured to advantageously manage the steady-state temperature of the OLED. The thermal junction may be formed with a thermal resistance of 0.2 m²·K/W or less. A distance across the junction may be 2 mm or less, and/or the junction may include a layer of material having a thermal conductivity of 0.1 W/m·K or greater.

### TECHNICAL FIELD

This disclosure relates to organic light-emitting diodes (OLEDs) and their operation in OLED devices.

### BACKGROUND

OLEDs have shown promise for use in various electronics display and lighting applications, due in part to their low deposition temperatures, mechanical flexibility, and low material cost. Being made partly with organic materials, OLEDs can be more sensitive to degradation by certain environmental factors than other types of LEDs. For example, exposure to oxygen, water, or other substances can negatively affect some OLED materials, rendering them non-functional or reducing their longevity as light-producing materials. OLED devices have been constructed to encapsulate OLEDs to protect them from the environment.

### SUMMARY

According to one embodiment, there is provided an OLED device. The device includes an OLED with an organic layer arranged between first and second electrodes. The device also includes a substrate supporting one side of the OLED and a cover layer at an opposite side of the OLED. A thermal junction included between the OLED and the cover layer has a thermal resistance of 0.2 m²·K/W or less.

In accordance with another embodiment, there is provided an OLED device. The device includes an OLED with an organic layer arranged between first and second electrodes. The device also includes a substrate supporting one side of the OLED and a cover layer at an opposite side of the OLED. A thermal junction included between the OLED and the cover layer is sized so that the OLED reaches a steady-state temperature within 10° C. of an ambient temperature at a luminance of 3000 cd/m².

In accordance with another embodiment, there is provided a method of making an OLED device. The method includes the steps of: (a) forming an OLED on a substrate; and (b) disposing a cover layer over the substrate to form a thermal junction between opposing surfaces of the OLED and the cover layer. The thermal junction has a thermal resistance of 0.2 m²·K/W or less.

In accordance with another embodiment, there is provided an electrically powered 3000 cd/m² light source with an encapsulated electroluminescent element that operates at a steady-state temperature within 1° C. of an ambient temperature.

### BRIEF DESCRIPTION OF THE DRAWINGS

Preferred exemplary embodiments will hereinafter be described in conjunction with the appended drawings, wherein like designations denote like elements, and wherein:

FIG. 1 is a schematic cross-sectional view of an OLED device, including a thermal junction between an OLED and a cover layer according to one embodiment;

FIG. 2 is a schematic cross-sectional view of an OLED device, including a thermal junction between an OLED and a cover layer according to another embodiment; and

FIG. 3 is a chart showing predicted operating temperatures of various OLED devices, each having a different thermal junction.

### DETAILED DESCRIPTION OF THE ILLUSTRATED EMBODIMENT(S)

As will become clear from the following disclosure, it is possible to construct an electrically powered light source with an electroluminescent element that can operate essentially at room temperature while providing a useful amount of light. Certain previously unrecognized characteristics of encapsulation structures can be used to manage the operating temperature of the encapsulated element. For example, a thermal junction may be formed within an OLED device and can be configured to have a thermal resistance sufficiently low to prevent thermal energy from being trapped within the device, thus lowering the operating temperature of the device and increasing its useful life.

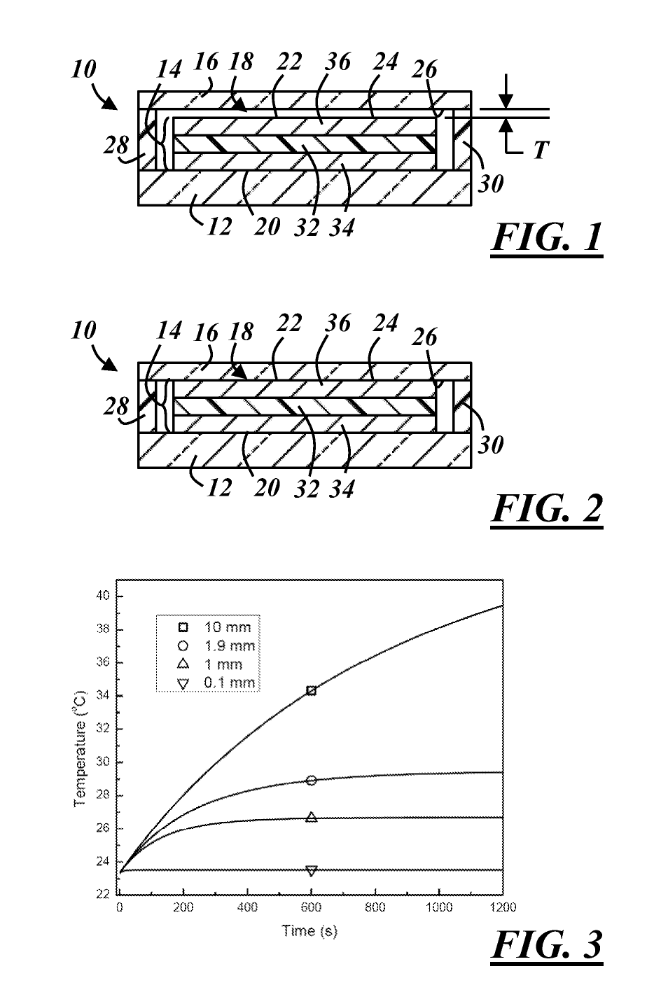

Referring to FIG. 1, an OLED device 10 is shown according to one embodiment. The device 10 includes a substrate 12, an OLED 14, a cover layer 16, and a thermal junction 18 between the OLED 14 and the cover layer 16. The substrate 12 supports the OLED 14 at a first side 20, and the cover layer 16 is at an opposite second side 22 of the OLED 14. In this particular embodiment, respective opposing surfaces 24 and 26 of the OLED 14 and the cover layer 16 are spaced apart by a distance T at the thermal junction 18. Distance T can range anywhere from 0 to 10 mm and affects the operation of the thermal junction 18 as described below. The spacing between opposing surfaces 24, 26 can be set during device construction by selection of appropriate spacer elements 28, 30, for example. These spacer elements may be located at or outside the periphery of the OLED 14 and can be constructed from any suitable material sufficient to reliably set distance T. In one embodiment, the spacer elements 28, 30 are formed from a curable adhesive material that holds the substrate 12 and the cover layer 16 together and/or helps seal the OLED 14 therebetween to protect it from the environment. The spacer elements 28, 30 may also be elements separate from any sealing or adhesive material such as integral extensions of the substrate 12 or cover layer 16.

OLED 14 includes an organic layer 32 arranged between first and second electrodes 34, 36. Organic layer 32 is the electroluminescent element of the device 10 and includes one or more layers of organic material that together produce light when a voltage is applied via electrodes 34, 36. Various types of materials that can be powered to produce light at desired wavelengths are known and can be used to form the organic layer 32. Electrodes 34, 36 are electrically conductive, and one or both may be formed from a material that is at least partly transparent. Indium tin oxide (ITO) is one example of an electrode material that is sufficiently transparent to allow light produced in the organic layer 32 to pass through to be emitted by the device 10. For example, the first electrode 34, located between the substrate 12 and the organic layer 32, may be at least partly transparent to form a bottom-emitting OLED that emits light toward the substrate 12. In another example, the second electrode 36, located between the cover layer 16 and the organic layer 32, is at least partly transparent to form a top-emitting OLED that emits light toward the cover layer 16. Or both of the electrodes 34, 36 can be at least partly transparent to allow emission of light in both directions. In one embodiment, one of the electrodes 34, 36 is at least partly transparent and the other of the electrodes is opaque and/or reflective to absorb or reflect light produced in the organic layer 32. For example, the non-transparent electrode may be a layer of metal such as aluminum that is sufficiently conductive to provide voltage to the organic layer 32 and sufficiently reflective to direct light back through the transparent electrode.

The illustrated OLED 14 is only one example of an OLED and could include various other elements or layers of material. For example, the OLED may include reflective layers separate from the electrodes or intervening layers that are located between the electrodes 34, 36 and the substrate 12 or cover layer 16 of the assembled device. Each of the illustrated OLED components typically range in thickness from about 0.1 μm to about 1.0 μm but are not limited to this range. Each OLED layer or element can be deposited over the substrate 12 by known techniques including vapor deposition, vapor jet printing, vapor thermal evaporation, or other techniques. Each of the substrate 12 and the cover layer 16 are provided in any material sufficient to help encase the OLED and provide other optional characteristics, such as transparency, opacity, rigidity, flexibility, etc. In one embodiment, the substrate and/or the cover layer is constructed from a suitable glass material, such as borosilicate glass, which may be useful in applications where rigidity is desired. In another embodiment, the substrate and/or the cover layer is constructed from a polymer material, which may be useful in applications where flexibility is desired.

Certain characteristics of the thermal junction 18 can predictably affect the operating temperature of the OLED in the device 10. For example, the size and the material composition of the thermal junction 18 can be varied to affect the operating temperature. The thermal junction 18 has a thermal resistance across the junction that is equal to the distance across the junction divided by the thermal conductivity of the material at the junction:

$$R = \frac{T}{λ} , \qquad ( 1 )$$

where R is the thermal resistance, T is the distance across the junction, and λ is thermal conductivity. Thermal conductivity is a material property that is known for many materials. Thermal junction 18 may include a layer of such a material or it may include a combination of different materials so that the value for thermal conductivity is a composite or effective value.

In one embodiment, the thermal junction 18 is constructed to have a thermal resistance of 0.2 m²·K/W or less. A thermal resistance in this range can be achieved with countless combinations of material types and layer thicknesses. For example, the thermal junction 18 may include a layer of material between the opposing surfaces 24, 26 that is 2 mm in thickness and has a thermal conductivity of 0.1 W/m·K. As indicated by Equation 1, thermal resistance is proportional to the distance across the thermal junction 18 and inversely proportional to the thermal conductivity of the material at the junction 18. In one embodiment, the thermal junction 18 includes a layer of material layer having a thermal conductivity of 0.1 W/m·K or greater. In another embodiment, opposing surfaces 24, 26 are spaced apart by 2 mm or less at the thermal junction. Greater material layer thickness or lower thermal conductivity at the junction 18 is also possible in certain combinations.

Where distance T is greater than zero, the junction may include one or more layers of any type of material, whether a solid, liquid, gas, or a phase change material. In one particular embodiment, the thermal junction includes a non-liquid material, such as a gas or a solid, which in some cases is easier to handle in a manufacturing environment compared to liquids. For example, solid material layers maintain their shape during handling or can be deposited using similar equipment as used with the OLED layers. A gas material layer can be formed by assembling the cover layer 16 over the OLED 14 and substrate in a gaseous environment to entrap the gas between the OLED 14 and cover layer 16. Gaseous thermal junction layers can also provide transparency to make top-emitting OLEDs possible. In one embodiment, the non-liquid material is air. In another embodiment, the non-liquid material is an inert gas such as argon.

FIG. 2 illustrates another embodiment of the OLED device 10 in which the OLED 14 and the cover layer 16 are in contact with each other at the thermal junction 18. In this particular embodiment, the opposing surfaces 24, 26 are in physical surface contact with each other, but the contact need not be full surface contact. In this case, the thermal resistance R across the thermal junction 18 is essentially zero because T=0. Physical contact between the cover layer 16 and the OLED 14 is somewhat unconventional, as cover layers have been developed with the focus being on protection of the OLED rather than on thermal management of the OLED. It is now recognized that minimization of distance T across the thermal junction 18 can be useful to lower the operating temperature of the OLED device 10, thereby extending its life. While the lowest operating temperatures may be obtained with distance T=0, in some cases it may be desirable to form junction 18 so that T>0 for other reasons. For example, it may be desirable to include a desiccant between the opposing surfaces 24, 26 at the junction 18 to draw water vapor away from the organic materials of the OLED. Or it may be desirable to immerse the OLED in an inert gas between the substrate 12 and the cover layer 16.

A recently developed transmission matrix method for calculating heat transfer characteristics was used to model various OLED device constructions to determine the degree to which each of the device layers contributes to the operating temperature of the device. This modeling confirmed that, with a gas layer such as air at the thermal junction, the distance T between the cover layer and the OLED has the greatest effect on heat transfer away from the OLED compared to other layer thicknesses. This modeling also indicates that with a thermal junction where T=0 or T is close to zero, the OLED can operate at or very near the ambient temperature outside the device.

Modeling was performed using device constructions layered as in FIGS. 1 and 2 with T ranging from 0.1 mm to 10 mm. The devices considered were 5 cm by 5 cm green OLEDs on a glass substrate with a glass cover layer. For the results shown in FIG. 3, the layer thicknesses and materials are given in TABLE I:

TABLE I

| Layer | Thickness (μm) | | Material |
|---|---|---|---|
| Substrate | 0.7 | mm | Glass |
| First Electrode | 1 | μm | ITO |
| Organic Layer | 0.1 | μm | — |
| Second Electrode | 0.1 | μm | Aluminum |
| Thermal Junction | 0.1-10 | mm | Air |
| Cover Layer | 0.7 | mm | Glass |

The simulated devices were operated at 114 W/m² of input thermal power, which corresponds to a luminance of 3000 cd/m², and the ambient temperature in which the simulated devices operated was 23.5° C. A steady-state temperature was determined for the OLED of each device according to a maximum temperature that each OLED asymptotically approached. As shown in FIG. 3, the OLED reached a steady-state temperature of approximately 29° C. when the thermal junction was a 1.9 mm thick layer of air. A thicker 10 mm air layer caused the OLED to have a steady-state temperature in excess of 40° C., and a thinner 1 mm air layer caused the OLED to have a steady-state temperature of about 26.5° C. Lowering the thickness of the thermal junction to 0.1 mm caused the steady-state temperature to be within less than 1° C. of the ambient temperature, between 23.5° C. and 23.6° C. As used here, the steady-state temperature is a substantially constant temperature approached over time. For example, in the mathematical models represented in FIG. 3, each OLED reaches a constant temperature that is the same as the steady-state temperature. In another example, the steady-state temperature is described by the temperature at which the average temperature varies by less than 0.1° C./hour, with the average being taken over the previous hour. Skilled artisans will appreciate that the steady-state temperature can be described in other ways for particular OLED devices, depending on the magnitude of particular temperature range, the time scale, or other factors.

OLED devices were also modeled by adjusting the thickness of the other layers, but none of these adjustments had a substantial effect on the steady-state temperature. Practical thicknesses for the OLED layers are too thin to substantially affect the heat transfer properties of the device, while increased glass thickness merely increased the time required for the device to reach steady-state without altering the steady-state temperature.

It is to be understood that the foregoing description is of one or more embodiments of the invention. The invention is not limited to the particular embodiment(s) disclosed herein, but rather is defined solely by the claims below. Furthermore, the statements contained in the foregoing description relate to the disclosed embodiment(s) and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that that the listing is not to be considered as excluding other, additional components or items. Other terms are to be construed using their broadest reasonable meaning unless they are used in a context that requires a different interpretation.

1. An organic light-emitting diode (OLED) device, comprising:
an OLED including an organic layer arranged between first and second electrodes;
a substrate supporting one side of the OLED;
a cover layer at an opposite side of the OLED; and
a thermal junction between the OLED and the cover layer having a thermal resistance of 0.2 m²·K/W or less.

2. An OLED device as defined in claim 1, wherein the thermal junction includes a non-liquid material.

3. An OLED device as defined in claim 1, wherein the thermal junction includes a layer of material having a thermal conductivity of 0.1 W/m·K or greater.

4. An OLED device as defined in claim 1, wherein opposing surfaces of the OLED and the cover layer are spaced apart by 2 mm or less at the thermal junction.

5. An OLED device as defined in claim 1, wherein the OLED and the cover layer are in contact with each other at the thermal junction.

6. An OLED device as defined in claim 1, wherein the cover layer is glass.

7. An OLED device as defined in claim 1, wherein the cover layer is polymeric.

8. An OLED device as defined in claim 1, wherein the substrate and the first electrode are at least partly transparent and the first electrode is between the substrate and the organic layer.

9. An OLED device as defined in claim 7, wherein the second electrode is opaque or at least partly reflective or both.

10. An OLED device as defined in claim 1, wherein the cover layer and the second electrode are at least partly transparent and the second electrode is between the cover layer and the organic layer.

11. An OLED device as defined in claim 10, wherein the thermal junction includes a layer of material that is at least partly transparent.

12. An organic light-emitting diode (OLED) device, comprising:
an OLED including an organic layer arranged between first and second electrodes;
a substrate supporting one side of the OLED;
a cover layer at an opposite side of the OLED; and
a thermal junction between the OLED and the cover layer, the thermal junction being sized so that the OLED reaches a steady-state temperature within 10° C. of an ambient temperature at a luminance of 3000 cd/m².

13. An OLED device as defined in claim 12, wherein the thermal junction is sized so that the OLED reaches a steady-state temperature within 1° C. of the ambient temperature.

14. An OLED device as defined in claim 12, wherein the thermal junction includes a non-liquid material.

15. An OLED device as defined in claim 12, wherein the thermal junction has a thermal resistance of 0.2 m²·K/W or less.

16. An OLED device as defined in claim 12, wherein opposing surfaces of the OLED and the cover layer are spaced apart by 2 mm or less at the thermal junction.

17. An OLED device as defined in claim 12, wherein the OLED and the cover layer are in contact with each other at the thermal junction.

18. An OLED device as defined in claim 12, wherein the OLED is a bottom-emitting OLED.

19. An OLED device as defined in claim 12, wherein the OLED is a top-emitting OLED.

20. A method of making an OLED device, comprising the steps of:
(a) forming an OLED on a substrate; and
(b) disposing a cover layer over the substrate to form a thermal junction between opposing surfaces of the OLED and the cover layer, the thermal junction having a thermal resistance of 0.2 m²·K/W or less.

21. The method of claim 20, further comprising the step of spacing said opposing surfaces from each other.

22. The method of claim 20, further comprising the step of bringing said opposing surfaces into physical contact with each other.

23. The method of claim 20, further comprising the step of sandwiching a non-liquid material between said opposing surfaces.

24. An electrically powered 3000 cd/m² light source comprising an encapsulated electroluminescent element that operates at a steady-state temperature within 1° C. of an ambient temperature.
